(19) United States
(12) Patent Application Publication
(10) Pub. No.: US 2013/0250540 A1
(43) Pub. Date: Sep. 26, 2013

(54) SHIELDING SHELL

(71) Applicant: Chih-Yuan Hou, New Taipei (TW)

(72) Inventor: Chih-Yuan Hou, New Taipei (TW)

(21) Appl. No.: 13/425,637

(22) Filed: Mar. 21, 2012

(51) Int. Cl. H05K 9/00

(52) U.S. Cl. 361/818

(57) ABSTRACT

A shielding shell includes a frame having a ring-shaped bracket with a receiving chamber therein. The bracket is erected on a printed circuit board with electronic components located in the receiving chamber. A top periphery of the bracket bends inward to form a support eave. At least three restricting portions of inverted-L shape protrude upward and inward at a rear and two symmetrical sides of the top periphery of the bracket respectively. An inserting slot is formed between the restricting portion and the support eave. A cover has a cover plate movably located on the support eave through a front of the frame and further pushed rearward to be inserted in the inserting slots so as to removably cover up the receiving chamber.

### BACKGROUND OF THE INVENTION

1. Field of the Invention

The present invention relates to a shielding shell, and more particularly to a shielding shell mounted on a circuit board for shielding electromagnetic interference.

2. The Related Art

With the wide use of electronic equipments in our daily life, electromagnetic waves are everywhere and often form a potential interference source that affects electrical circuits of the electronic equipments easily. The electromagnetic interference is a kind of electromagnetic phenomenon produced along with the change of electrical currents and voltages. The electromagnetic interference may interrupt, obstruct, or otherwise degrade or limit the effective performance of the electrical circuit. These effects can range from a simple degradation of data to a total loss of data. A common means of reducing the electromagnetic interference is: fixing or soldering a shielding shell on a printed circuit board for shielding the electromagnetic interference. However, if a repair operation needs to be performed for electronic components on the printed circuit board, it is an inevitable procedure to remove the shielding shell from the printed circuit board by damaging or disoldering the shielding shell. As a result, not only this procedure is very inconvenient, but also the shielding shell may be easily damaged in the process of being disoldered or should be directly damaged. So, it not only causes material waste, but also takes a long time of repair work hours, and finally fails to effectively achieve human and material cost control.

### SUMMARY OF THE INVENTION

An object of the present invention is to provide a shielding shell adapted for being mounted on a printed circuit board to surround electronic components of the printed circuit board for shielding electromagnetic interference. The shielding shell includes a frame and a cover. The frame has a ring-shaped bracket with a receiving chamber therein. The bracket is erected on the printed circuit board with the electronic components located in the receiving chamber. A top periphery of the bracket bends inward to form a support eave which is parallel to a top face of the printed circuit board and slightly higher than the peak of a highest electronic component. At least three restricting portions of inverted-L shape protrude upward and then inward at a rear and two symmetrical sides of the top periphery of the bracket respectively. An inserting slot is formed between the restricting portion and the support eave. The cover has a cover plate of which an outline is substantially in accordance with the bracket and an area is slightly greater than the receiving chamber. The cover plate is movably located on the support eave through a front of the frame and further pushed rearward to be inserted in the inserting slots so as to removably cover up the receiving chamber.

As described above, the cover is removably assembled to the frame so that not only can completely enclose the electronic components of the printed circuit board in the shielding shell to effectively shield the electromagnetic interference, but also can conveniently repair the electronic components by removing the cover from the frame to expose the electronic components outside, without damaging the frame and the cover. So, it not only effectively economizes material waste, but also greatly improves repair efficiency, and finally effectively realizes human and material cost control.

### BRIEF DESCRIPTION OF THE DRAWINGS

The present invention will be apparent to those skilled in the art by reading the following description with reference to the attached drawings, in which:

FIG. 1 is an exploded perspective view of a shielding shell in accordance with an embodiment of the present invention; and

FIG. 2, FIG. 3 and FIG. 4 are using state views showing that the shielding shell of FIG. 1 is assembled on a printed circuit board.

### DETAILED DESCRIPTION OF THE PREFERRED EMBODIMENT

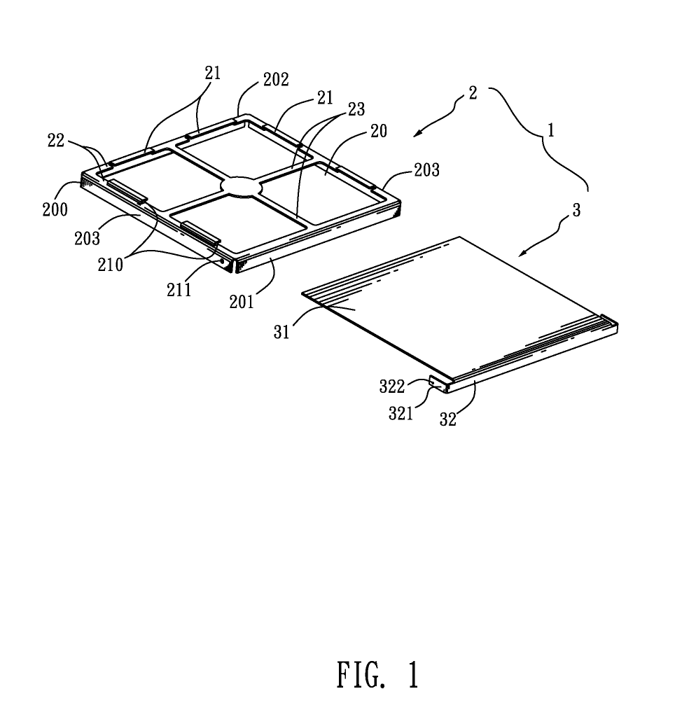

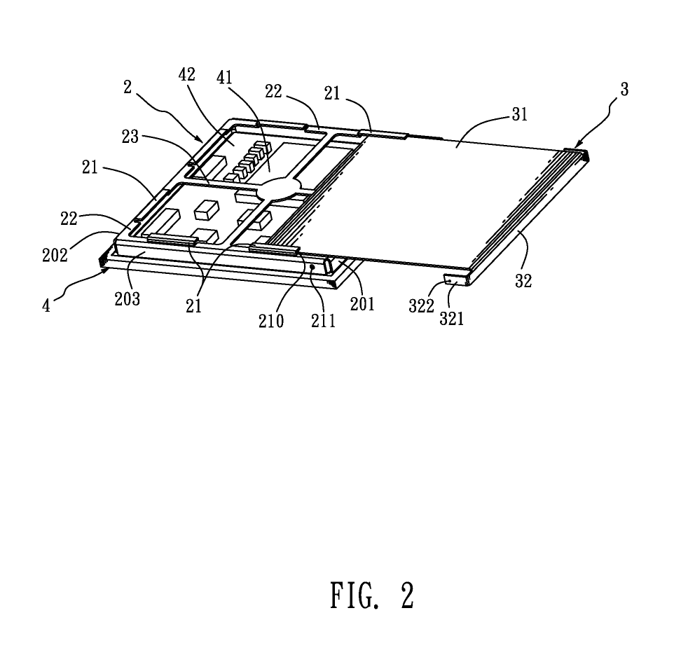

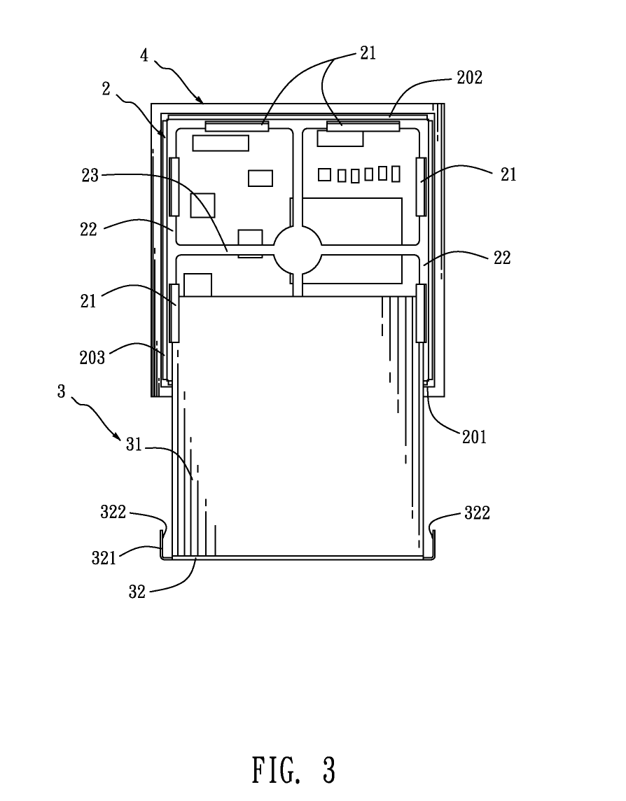

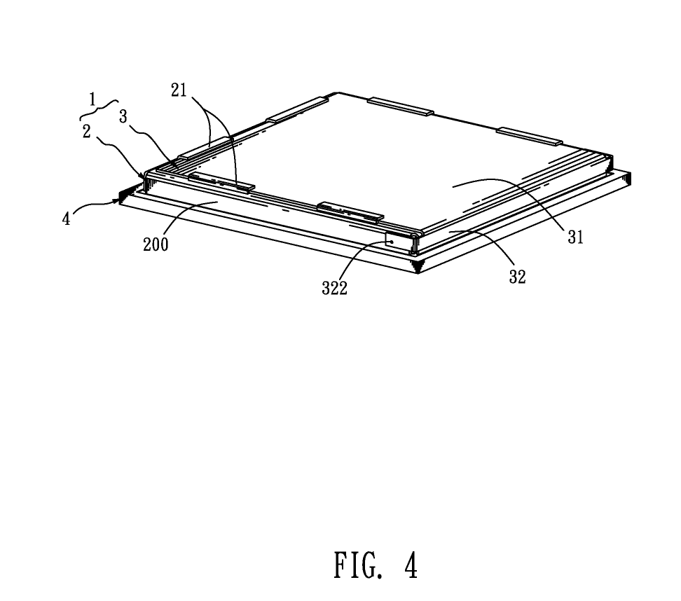

Referring to FIG. 1 and FIG. 2, a shielding shell 1 according to an embodiment of the present invention is adapted for being mounted on a printed circuit board 4 to surround electronic components 41 of the printed circuit board 4 therein for shielding electromagnetic interference. The shielding shell 1 includes a frame 2 and a cover 3.

Referring to FIGS. 1-4, the frame 2 has a ring-shaped bracket 200 with a receiving chamber 20 therein. The bracket 200 is erected on the printed circuit board 4 with the electronic components 41 located in the receiving chamber 20. A top periphery of the bracket 200 bends inward to form a support eave 22 which is parallel to a top face 42 of the printed circuit board 4 and slightly higher than the peak of the highest one of the electronic components 41. At least three restricting portions 21 of inverted-L shape protrude upward and then inward at a rear and two symmetrical sides of the top periphery of the bracket 200 respectively. An inserting slot 210 is formed between the restricting portion 21 and the support eave 22. The cover 3 has a cover plate 31 of which an outline is substantially in accordance with the bracket 200 and an area is slightly greater than the receiving chamber 20. The cover plate 31 is movably located on the support eave 22 through a front of the frame 2 and further pushed rearward to be inserted in the inserting slots 210 so as to removably cover up the receiving chamber 20. So, the shielding shell 1 can completely enclose the electronic components 41 of the printed circuit board 4 therein to effectively shield electromagnetic interference. When some electronic components 41 need to be repaired, pull the cover 3 forward until the cover plate 31 moves out of the inserting slots 210. At this moment, remove the cover 3 from the frame 2 so as to expose the electronic components 41 outside for the convenience of the repair operation.

Referring to FIG. 1 and FIG. 4, the bracket 200 defines a pair of latching structures 211 at two fronts of two opposite sides thereof. A pair of latching arms 321 is freely located at two opposite sides of a front of the cover plate 31 and each defines a latching portion 322 thereon for buckling with the latching structure 211 of the frame 2 to secure the cover 3 and the frame 2 together.

In this embodiment, the bracket 200 is substantially of a rectangular shape and has a front strip 201, two opposite side strips 203 and a rear strip 202. The top periphery of the side strips 203 and the rear strip 202 each protrudes to form two restricting portions 21. The latching structures 211 form at two front ends of the side strips 203. The cover plate 31 is of a flat rectangular board shape and a front edge thereof bends downward to form a resisting strip 32 of which two opposite ends extend rearward to form the latching arms 321.

Referring to FIGS. 1-4 again, a support cross 23 is connected with an inner periphery of the support eave 22 of the frame 2 and located over the receiving chamber 20 for strengthening the support eave 22 of the frame 2 and further bearing the cover plate 31 thereon. In this embodiment, the frame 2 and the cover 3 are made of metal material.

As described above, the cover 3 is removably assembled to the frame 2 so that not only can completely enclose the electronic components 41 of the printed circuit board 4 in the shielding shell 1 to effectively shield the electromagnetic interference, but also can conveniently repair the electronic components 41 by removing the cover 3 from the frame 2 to expose the electronic components 41 outside, without damaging the frame 2 and the cover 3. So, it not only effectively economizes material waste, but also greatly improves repair efficiency, and finally effectively realizes human and material cost control.

What is claimed is:

1. A shielding shell adapted for being mounted on a printed circuit board to surround electronic components of the printed circuit board for shielding electromagnetic interference, comprising:
a frame having a ring-shaped bracket with a receiving chamber therein, the bracket being erected on the printed circuit board with the electronic components located in the receiving chamber, a top periphery of the bracket bending inward to form a support eave which is parallel to a top face of the printed circuit board and slightly higher than the peak of a highest electronic component, at least three restricting portions of inverted-L shape protruding upward and then inward at a rear and two symmetrical sides of the top periphery of the bracket respectively, an inserting slot being formed between the restricting portion and the support eave; and
a cover having a cover plate of which an outline is substantially in accordance with the bracket and an area is slightly greater than the receiving chamber, the cover plate being movably located on the support eave through a front of the frame and further pushed rearward to be inserted in the inserting slots so as to removably cover up the receiving chamber.

2. The shielding shell as claimed in claim 1, wherein the bracket defines a pair of latching structures at two fronts of two opposite sides thereof, a pair of latching arms is freely located at two opposite sides of a front of the cover plate and each defines a latching portion thereon for buckling with the latching structure of the frame to secure the cover and the frame together.

3. The shielding shell as claimed in claim 2, wherein the bracket is substantially of a rectangular shape and has a front strip, two opposite side strips and a rear strip, the top periphery of the side strips and the rear strip each protrudes to form two restricting portions, the latching structures form at two front ends of the side strips, the cover plate is of a flat rectangular board shape and a front edge thereof bends downward to form a resisting strip of which two opposite ends extend rearward to form the latching arms.

4. The shielding shell as claimed in claim 1, wherein a support cross is connected with an inner periphery of the support eave of the frame and located over the receiving chamber for strengthening the support eave of the frame and further bearing the cover plate thereon.

5. The shielding shell as claimed in claim 1, wherein the frame and the cover are made of metal material.
